(19) United States
(12) Patent Application Publication
(10) Pub. No.: US 2009/0165856 A1
(43) Pub. Date: Jul. 2, 2009

(54) High-efficiency solar cell and method of manufacturing the same

(75) Inventors: Ro Woon Lee, Seoul (KR); Jae Woo Joung, Gyeonggi-do (KR); Sung Jun Park, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/081,427

(22) Filed: Apr. 16, 2008

(30) Foreign Application Priority Data
Jan. 2, 2008 (KR) 10-2008-0000142

(51) Int. Cl. H01L 31/06; H01L 31/0264; H01L 31/18

(52) U.S. Cl. 136/261; 438/98; 257/E31.004

(57) ABSTRACT

Provided is a high-efficiency solar cell including a back contact formed on a substrate; a conductive carbon nanotube array formed on the top surface of the back contact; a p-type semiconductor layer formed between a plurality of multi-wall carbon nanotubes composing the conductive carbon nanotube array and on the conductive carbon nanotube array; an n-type semiconductor layer formed on the top surface of the p-type semiconductor layer; and a transparent electrode formed on the top surface of the n-type semiconductor layer and composed of a plurality of hemispheric microlenses.

### CROSS-REFERENCE TO RELATED APPLICATIONS

This application claims the benefit of Korean Patent Application No. 10-2008-0000142 filed with the Korea Intellectual Property Office on Jan. 2, 2008, the disclosure of which is incorporated herein by reference.

### BACKGROUND OF THE INVENTION

1. Field of the Invention

The present invention relates to a high-efficiency solar cell and a method of manufacturing the same.

2. Description of the Related Art

Solar cells, which convert light energy of the sun into electric energy by using a p-n junction characteristic of semiconductor, are considered as a next-generation energy source. Solar cells are divided into a superstrate-type solar cell and a substrate-type solar cell depending on a manufacturing method. The superstrate-type solar cell uses glass as a substrate, and the substrate-type solar cell uses silicon as a substrate.

The substrate-type solar cell is manufactured through a silicon semiconductor process. Although the manufacturing process is complicated and a material cost of the substrate-type solar cell is high, the energy efficiency thereof is higher than other solar cells. Therefore, the substrate-type solar cell is used for mass production.

FIGS. 1A to 1F are diagrams showing a process of manufacturing a conventional superstrate-type solar cell.

As shown in the drawings, a transparent conducting oxide (TCO) is deposited on a substrate 11 composed of glass, and n-type and p-type semiconductors 13 and 14 are sequentially deposited to form p-n junction. Further, front and rear electrodes 15 and 16 are formed on the TCO 12 and the p-type semiconductor 14, respectively. Then, the process of manufacturing the solar cell is completed. While light incident on a glass surface passes through the TCO and the n-type semiconductor so as to be absorbed by the p-type semiconductor, excited electrons are flown by an electromotive force, which makes it possible to obtain electric power.

The solar cell manufactured in such a manner is a semiconductor element which converts solar energy into electric energy. The solar cell has a junction form of p-type and n-type semiconductors, and the basic structure thereof is identical to that of diodes. That is, when light is incident on the solar cell from outside, conduction-band electrons of the p-type semiconductor are excited into a valence band by the incident light energy. The excited electrons form one electron-hole pair in the p-type semiconductor. In the p-type semiconductor of the solar cell, however, recombination of the excited electrons and holes occurs because of a polycrystalline material characteristic and a junction with a different interface. This may degrade the efficiency of the solar cell.

Recently, attempts to introduce an inkjet printing technique in the manufacturing process of solar cells are being actively carried out.

The inkjet technique was developed by Kyzer and Zaltan in 1970. At this time, a drop on demand (DOD) inkjet printing method was developed and has been utilized for industrial use. In the early 1980's, HP, Canon and so on developed a thermal inkjet head, and Epson developed a piezoelectric inkjet head. Then, the application of the inkjet technique into printers has begun in earnest.

Currently, industrial inkjet heads are being used in various fields. In particular, an attempt to use an inkjet head to form a masking pattern for patterning is being carried out in the solar-cell field. The inkjet technique has an advantage in terms of time and space, and an intermediate process can be omitted. Therefore, it is possible to reduce a manufacturing cost.

### SUMMARY OF THE INVENTION

An advantage of the present invention is that it provides a high-efficiency solar cell in which a conductive carbon nanotube array is formed in a p-type semiconductor layer of the solar cell, thereby enhancing conversion efficiency. Further, a transparent electrode is formed in the form of semi-circular microlens by using the inkjet technique. Therefore, it is possible to minimize a loss in light entering the transparent electrode.

Additional aspects and advantages of the present general inventive concept will be set forth in part in the description which follows and, in part, will be obvious from the description, or may be learned by practice of the general inventive concept.

According to an aspect of the invention, a high-efficiency solar cell comprises a back contact formed on a substrate; a conductive carbon nanotube array formed on the top surface of the back contact; a p-type semiconductor layer formed between a plurality of multi-wall carbon nanotubes composing the conductive carbon nanotube array and on the conductive carbon nanotube array; an n-type semiconductor layer formed on the top surface of the p-type semiconductor layer; and a transparent electrode formed on the top surface of the n-type semiconductor layer and composed of a plurality of hemispheric microlenses.

Preferably, the substrate is formed of any one of copper (Cu), aluminum (Al), stainless steel, and silicon wafer, and has a thickness of 0.5 to 1 mm.

Preferably, the back contact is formed of molybdenum (Mo).

The respective carbon nanotubes composing the conductive carbon nanotube array may have a thickness of 1 to 2 μm.

Preferably, the p-type semiconductor layer has a thickness of 3 μm.

Preferably, the respective hemispheric microlenses composing the transparent electrode have a diameter of 0.5 to 1 μm.

According to another aspect of the invention, a high-efficiency solar cell comprises a back contact formed on a substrate; a p-type semiconductor layer formed on the back contact; an n-type semiconductor layer formed on the p-type semiconductor layer; and a transparent electrode formed on the n-type semiconductor layer and composed of a plurality of hemispheric microlenses.

Preferably, the substrate is formed of any one of Cu, Al, stainless steel, and silicon wafer, and has a thickness of 0.5 to 1 mm.

Preferably, the back contact is formed of Mo.

Preferably, the p-type semiconductor layer has a thickness of 3 μm.

Preferably, the respective hemispheric microlenses composing the transparent electrode have a diameter of 0.5 to 1 μm.

According to a further aspect of the invention, a method of manufacturing a high-efficiency solar cell comprises the steps of: forming a back contact on a substrate; forming a conductive carbon nanotube array on the top surface of the back contact; forming a p-type semiconductor layer between a plurality of carbon nanotubes composing the conductive carbon nanotube array and on the conductive carbon nanotube array; forming an n-type semiconductor layer on the top surface of the p-type semiconductor layer; and forming a transparent electrode on the top surface of the n-type semiconductor layer, the transparent electrode being composed of a plurality of hemispheric microlenses.

Preferably, the back contact is formed by printing conductive ink on the substrate through an inkjet head. Further, the conductive ink is composed of Mo.

The forming of the conductive carbon nanotube array may include the steps of: forming a plurality of transition metal layers on the back contact, the transition metal layers having a length of 3 to 10 μm; and forming a plurality of carbon nanotubes on the top surfaces of the respective transition metal layers through a plasma-enhanced chemical vapor deposition (PECVD) method.

Preferably, the transition metal layers are formed by sputtering iron (Fe) or nickel (Ni).

The n-type semiconductor layer may be formed by printing n-type semiconductor on the top surface of the p-type semiconductor layer through an inkjet head.

Preferably, the transparent electrode is formed by printing ink for transparent electrode on the top surface of the n-type semiconductor layer through an inkjet head. Further, the respective hemispheric microlenses composing the transparent electrode have a diameter of 0.5 to 1 μm.

According to a still further aspect of the invention, a method of manufacturing a high-efficiency solar cell comprises the steps of: forming a back contact on a substrate; forming a p-type semiconductor layer on the top surface of the back contact; forming an n-type semiconductor layer on the top surface of the p-type semiconductor layer; and forming a transparent electrode on the top surface of the n-type semiconductor layer, the transparent electrode being composed of a plurality of hemispheric microlenses.

Preferably, the back contact is formed by printing conductive ink on the substrate through an inkjet head. Further, the conductive ink is composed of Mo.

Preferably, the n-type semiconductor layer is formed by printing n-type semiconductor on the top surface of the p-type semiconductor layer through an inkjet head.

Preferably, the transparent electrode is formed by printing ink for transparent electrode on the top surface of the n-type semiconductor layer through an inkjet head. Further, the respective hemispheric microlenses composing the transparent electrode have a diameter of 0.5 to 1 μm.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1A to 1F are diagrams showing a process of manufacturing a conventional superstrate-type solar cell;

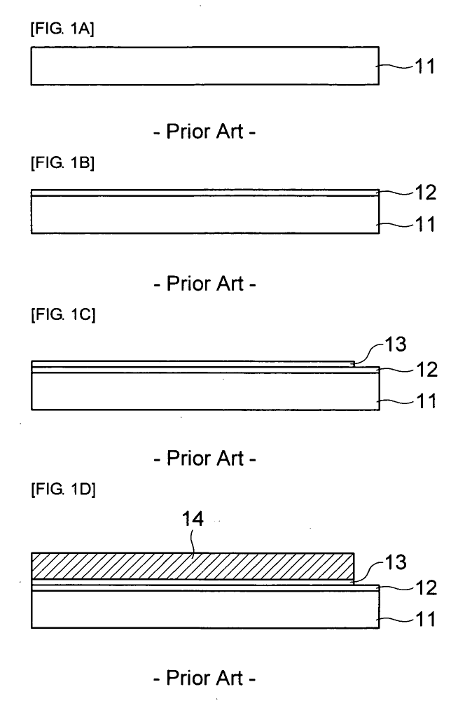

FIG. 2A is a diagram showing a state where droplets with a size of several tens μm are ejected from an inkjet head;

FIG. 2B is a photograph showing a state where the droplets are received on a substrate;

FIG. 3 is a side cross-sectional view of a high-efficiency solar cell according to the invention;

FIG. 4 is an expanded view of a transparent electrode of the high-efficiency solar cell according to the invention; and

FIGS. 5A to 5K are process diagrams showing a method of manufacturing the high-efficiency solar cell according to an embodiment of the invention.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a high-efficiency solar cell and a method of manufacturing the same according to the present invention will be described in detail with reference to the accompanying drawings.

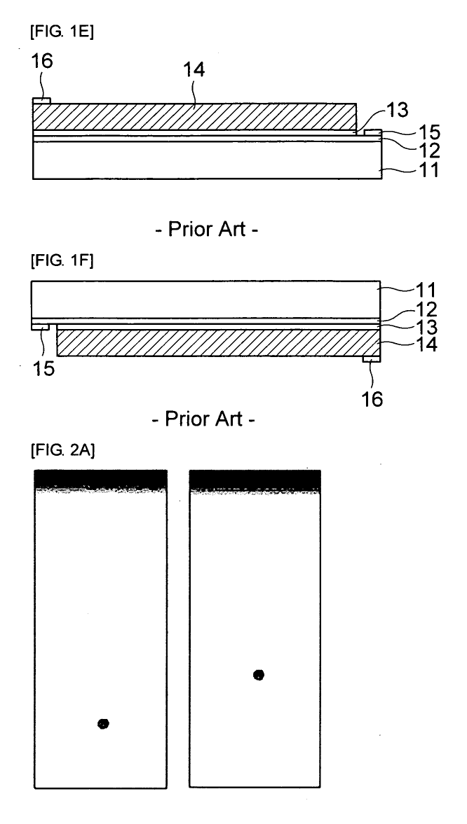

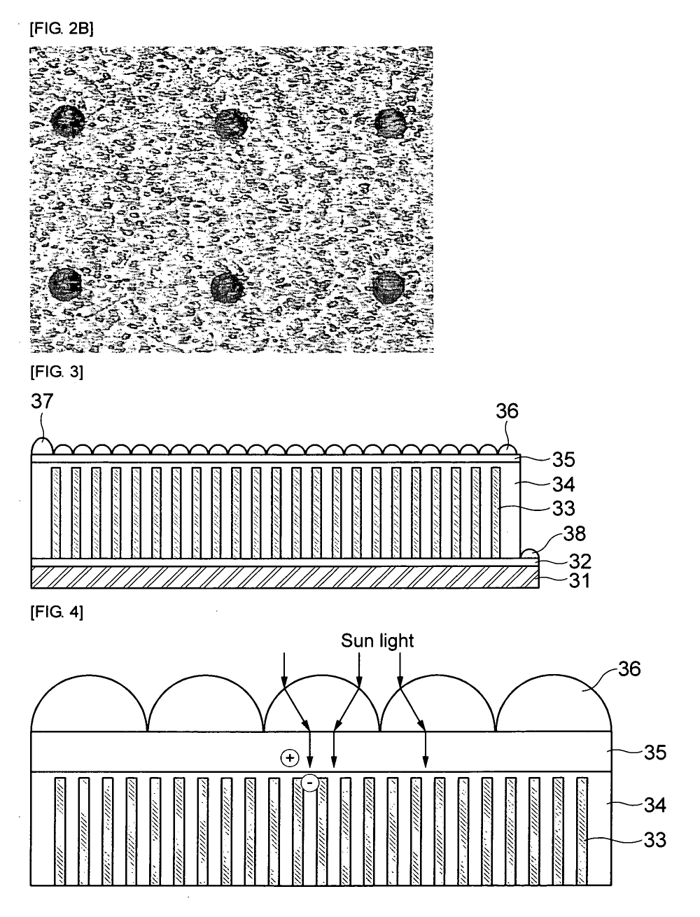

FIG. 2A shows a state where droplets with a size of several tens μm are ejected from an inkjet head. FIG. 2B shows a state where the droplets are received on a substrate.

As shown in FIGS. 2A and 2B, while the droplets ejected from the inkjet head are received on the substrate, they form hemispheric patterns with a size of several tens μm. As ink for transparent electrode is jetted by using an inkjet technology, a transparent electrode of a solar cell can be formed in the form of microlens. The transparent electrode manufactured in such a manner reduces a loss in incident light, and simultaneously serves as a condenser. Therefore, it is possible to manufacture a high-efficiency solar cell.

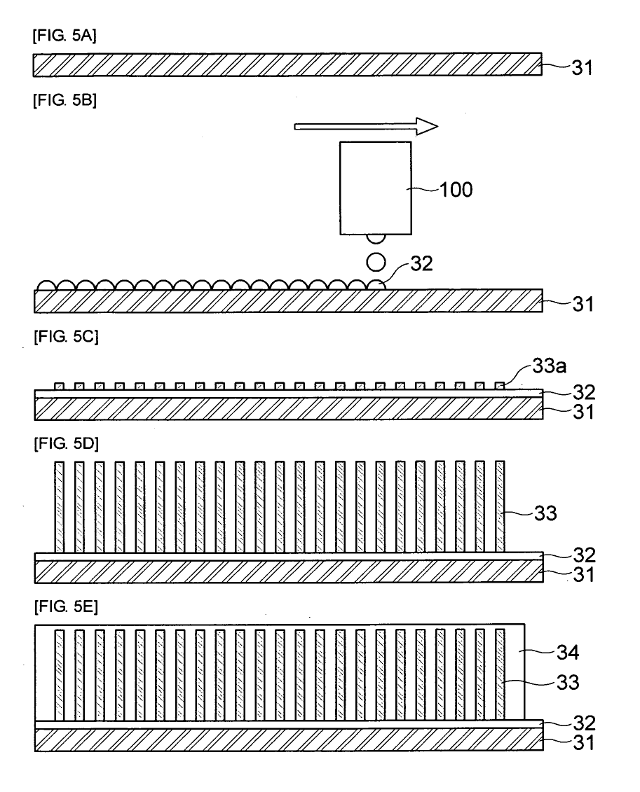

FIG. 3 is a side cross-sectional view of a high-efficiency solar cell according to the invention.

As shown in FIG. 3, the high-efficiency solar cell includes a substrate 31, a back contact 32 formed on the substrate 31, a conductive carbon nanotube array 33 formed on the top surface of the back contact 32, a p-type semiconductor layer 34 formed between a plurality of carbon nanotubes composing the conductive carbon nanotube array 33 and on the conductive carbon nanotube array 33, an n-type semiconductor layer 35 formed on the top surface of the p-type semiconductor layer 34, a transparent electrode 36 formed on the top surface of the n-type semiconductor layer 35, a front electrode 37 connected to the n-type semiconductor layer 35, and a rear electrode 38 connected to the back contact 32.

In the present invention, the substrate 31 is formed of any one of copper (Cu), aluminum (Al), stainless steel, and silicon wafer. The substrate 31 has a thickness of 0.5 to 1 mm.

Preferably, the back contact 32 is formed of molybdenum (Mo) and is formed by printing conductive ink on the substrate through an inkjet head.

The carbon nanotube array 33 formed on the back contact 32 is composed of the plurality of multi-wall carbon nanotubes. Each of the carbon nanotubes has a thickness of 1 to 2 μm.

Between the respective carbon nanotubes composing the carbon nanotube array 33 and on the carbon nanotube array 33, the p-type semiconductor layer 34 is formed. Preferably, the p-type semiconductor layer 34 has a thickness of 3 μm.

The n-type semiconductor layer 35 is formed on the top surface of the p-type semiconductor layer 34. Like the back contact 32, the n-type semiconductor layer 35 is formed by the printing method using the inkjet head.

The transparent electrode 36 is formed on the top surface of the n-type semiconductor layer 35. The transparent electrode 36 is formed in the form of microlenses by printing ink for transparent electrode through the inkjet head. As described above, the transparent electrode 36 manufactured in such a manner reduces a loss in incident light, and simultaneously serves as a condenser.

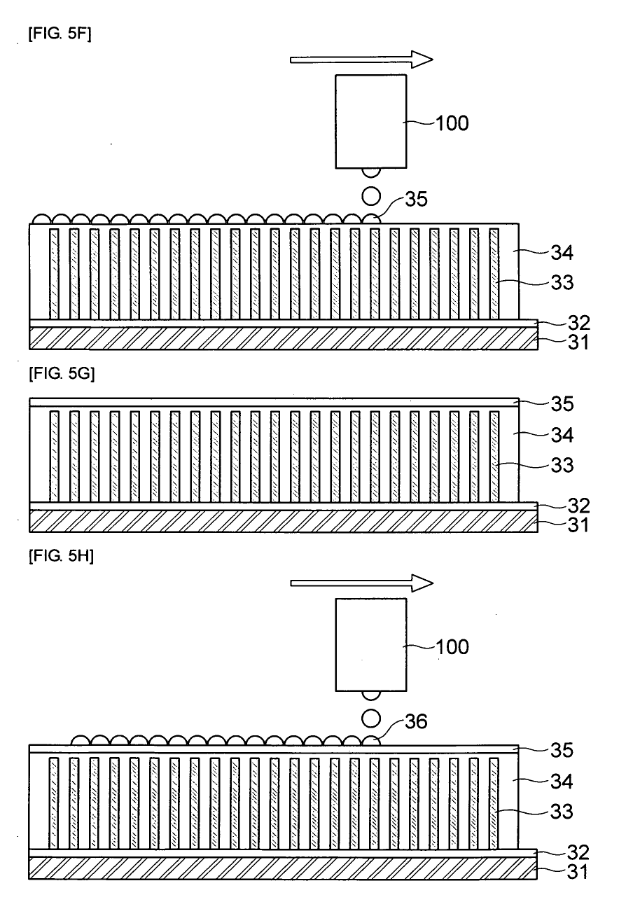

FIG. 4 is an expanded view of the transparent electrode of the high-efficiency solar cell according to the invention.

As shown in FIG. 4, since the transparent electrode 36 is formed in the form of hemispheric microlens, incident sunlight is condensed through the transparent electrode 36. The transparent electrode 36 constructed in such a manner reduces a loss in incident light, thereby enhancing photon efficiency. Therefore, it is possible to manufacture a high-efficiency solar cell.

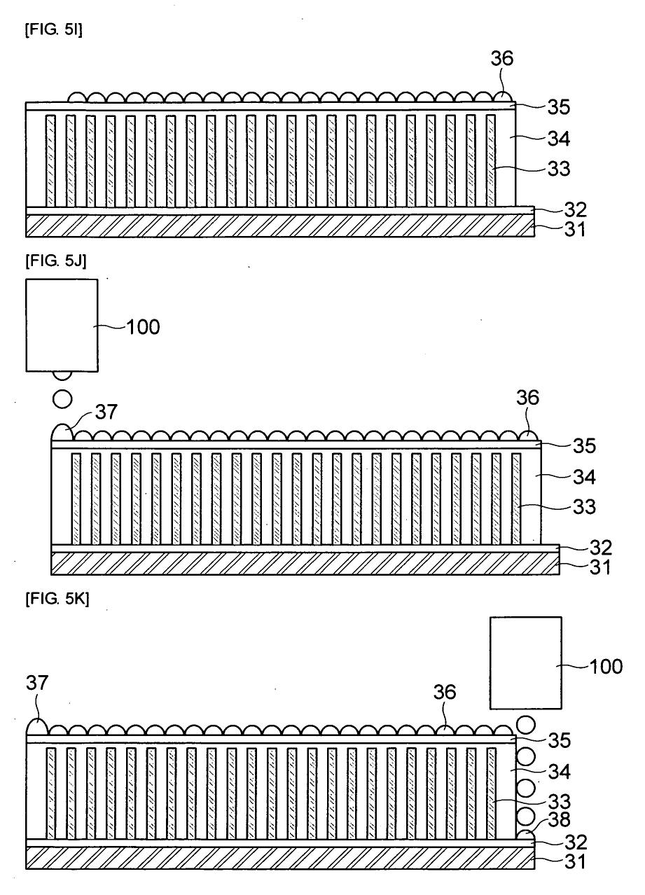

FIGS. 5A to 5K are process diagrams showing a method of manufacturing the high-efficiency solar cell according to an embodiment of the invention.

As shown in FIGS. 5A and 5B, a back contact 32 is formed on a substrate 31. Preferably, the back contact 32 is composed of Mo and is formed by printing conductive ink on the substrate 31 through an inkjet head 100, the conductive ink including Mo.

Then, as shown in FIG. 5C, a plurality of transition metal layers 33a are deposited on the back contact 32. The deposition of the transition metal layers 33a may be performed by a typical sputtering method. Preferably, the transition metal layers 33a are formed of Fe or Ni.

Next, as shown in FIG. 5D, a conductive carbon nanotube array 33 is formed on the transition metal layers 33a by a plasma-enhanced chemical vapor deposition (PECVD) method. Preferably, the carbon nanotube array 33 has a thickness of 1 to 2 μm.

Subsequently, as shown in FIG. 5E, a p-type semiconductor layer 34 is formed between the respective carbon nanotubes composing the conductive carbon nanotube array 33 and on the conductive carbon nanotube array 33. Preferably, the p-type semiconductor layer 34 has a thickness of about 3 μm.

Next, as shown in FIG. 5F, an n-type semiconductor layer 35 is formed on the top surface of the p-type semiconductor layer 34. The n-type semiconductor layer 35 is also formed by the printing method using the inkjet head 100.

Then, as shown in FIG. 5G, the n-type semiconductor layer 35 formed through the inkjet head 100 is fixed by a poat baking process. In this process, the solar cell having the n-type semiconductor layer 35 formed therein is heated at a temperature of 120 to 200° C. for 20 to 30 minutes.

Next, as shown in FIG. 5H, a transparent electrode 36 composed of a plurality of hemispheric microlenses is formed on the top surface of the n-type semiconductor layer 35. The transparent electrode 36 is also formed by printing ink for transparent electrode on the n-type semiconductor layer 35 through the inkjet head 100. In this process, the nozzle of the inkjet head 100 is controlled to print hemispheric droplets on the n-type semiconductor layer 35 such that the hemispheric droplets do not overlap each other, as described in FIG. 2B. Preferably, the hemispheric microlenses composing the transparent electrode 36 have a diameter of 0.5 to 1 μm.

Subsequently, as shown in FIG. 5I, the transparent electrode 36 is fixed through the poat baking process. This process is performed in the same manner as described in FIG. 5G.

Finally, as shown in FIGS. 5J and 5K, a front electrode 37 is formed so as to be connected to the n-type semiconductor layer 35, and a rear electrode 38 is formed so as to be connected to the back contact 32. Preferably, the front and rear electrodes 37 and 38 are formed using the inkjet head 100.

According to the invention, the conductive carbon nanotube array is formed in the p-type semiconductor layer of the solar cell, thereby maximizing a surface area of p-n junction. Therefore, it is possible to provide a high-efficiency solar cell with excellent conversion efficiency.

Further, as the transparent electrode is manufactured in the form of hemispheric microlens by the inkjet technology, it is possible to reduce a loss in light entering the transparent electrode and to increase photon efficiency.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A high-efficiency solar cell comprising:
a back contact formed on a substrate;
a conductive carbon nanotube array formed on the top surface of the back contact;
a p-type semiconductor layer formed between a plurality of multi-wall carbon nanotubes composing the conductive carbon nanotube array and on the conductive carbon nanotube array;
an n-type semiconductor layer formed on the top surface of the p-type semiconductor layer; and
a transparent electrode formed on the top surface of the n-type semiconductor layer and composed of a plurality of hemispheric microlenses.

2. The high-efficiency solar cell according to claim 1, wherein the substrate is formed of any one of copper (Cu), aluminum (Al), stainless steel, and silicon wafer, and has a thickness of 0.5 to 1 mm.

3. The high-efficiency solar cell according to claim 1, wherein the back contact is formed of molybdenum (Mo).

4. The high-efficiency solar cell according to claim 1, wherein the respective carbon nanotubes composing the conductive carbon nanotube array have a thickness of 1 to 2 μm.

5. The high-efficiency solar cell according to claim 1, wherein the p-type semiconductor layer has a thickness of 3 μm.

6. The high-efficiency solar cell according to claim 1, wherein the respective hemispheric microlenses composing the transparent electrode have a diameter of 0.5 to 1 μm.

7. A high-efficiency solar cell comprising:
a back contact formed on a substrate;
a p-type semiconductor layer formed on the back contact;
an n-type semiconductor layer formed on the p-type semiconductor layer; and
a transparent electrode formed on the n-type semiconductor layer and composed of a plurality of hemispheric microlenses.

8. The high-efficiency solar cell according to claim 7, wherein the substrate is formed of any one of Cu, Al, stainless steel, and silicon wafer, and has a thickness of 0.5 to 1 mm.

9. The high-efficiency solar cell according to claim 7, wherein the back contact is formed of Mo.

10. The high-efficiency solar cell according to claim 7, wherein the p-type semiconductor layer has a thickness of 3 μm.

11. The high-efficiency solar cell according to claim 7, wherein the respective hemispheric microlenses composing the transparent electrode have a diameter of 0.5 to 1 μm.

12. A method of manufacturing a high-efficiency solar cell, comprising the steps of:
forming a back contact on a substrate;
forming a conductive carbon nanotube array on the top surface of the back contact;
forming a p-type semiconductor layer between a plurality of carbon nanotubes composing the conductive carbon nanotube array and on the conductive carbon nanotube array;
forming an n-type semiconductor layer on the top surface of the p-type semiconductor layer; and
forming a transparent electrode on the top surface of the n-type semiconductor layer, the transparent electrode being composed of a plurality of hemispheric microlenses.

13. The method according to claim 12, wherein the back contact is formed by printing conductive ink on the substrate through an inkjet head.

14. The method according to claim 13, wherein the conductive ink is composed of Mo.

15. The method according to claim 12, wherein the forming of the conductive carbon nanotube array includes the steps of:
forming a plurality of transition metal layers on the back contact, the transition metal layers having a length of 3 to 10 μm; and
forming a plurality of carbon nanotubes on the top surfaces of the respective transition metal layers through a plasma-enhanced chemical vapor deposition (PECVD) method.

16. The method according to claim 15, wherein the transition metal layers are formed by sputtering iron (Fe) or nickel (Ni).

17. The method according to claim 12, wherein the n-type semiconductor layer is formed by printing n-type semiconductor on the top surface of the p-type semiconductor layer through an inkjet head.

18. The method according to claim 12, wherein the transparent electrode is formed by printing ink for transparent electrode on the top surface of the n-type semiconductor layer through an inkjet head.

19. The method according to claim 12, wherein the respective hemispheric microlenses composing the transparent electrode have a diameter of 0.5 to 1 μm.

20. A method of manufacturing a high-efficiency solar cell, comprising the steps of:
forming a back contact on a substrate;
forming a p-type semiconductor layer on the top surface of the back contact;
forming an n-type semiconductor layer on the top surface of the p-type semiconductor layer; and
forming a transparent electrode on the top surface of the n-type semiconductor layer, the transparent electrode being composed of a plurality of hemispheric microlenses.

21. The method according to claim 20, wherein the back contact is formed by printing conductive ink on the substrate through an inkjet head.

22. The method according to claim 21, wherein the conductive ink is composed of Mo.

23. The method according to claim 20, wherein the n-type semiconductor layer is formed by printing n-type semiconductor on the top surface of the p-type semiconductor layer through an inkjet head.

24. The method according to claim 20, wherein the transparent electrode is formed by printing ink for transparent electrode on the top surface of the n-type semiconductor layer through an inkjet head.

25. The method according to claim 20, wherein the respective hemispheric microlenses composing the transparent electrode have a diameter of 0.5 to 1 μm.
